(19) United States
(12) Patent Application Publication
(10) Pub. No.: US 2010/0270580 A1
(43) Pub. Date: Oct. 28, 2010

(54) SUBSTRATE BASED LIGHT SOURCE PACKAGE WITH ELECTRICAL LEADS

(76) Inventor: Jason Loomis Posselt, San Jose, CA (US)

Correspondence Address: THE LAW OFFICES OF CALVIN B. WARD, 18 CROW CANYON COURT, SUITE 305, SAN RAMON, CA, 94583, US

(21) Appl. No.: 12/428,389

(22) Filed: Apr. 22, 2009

(51) Int. Cl. H01L 33/00; H01L 21/00

(52) U.S. Cl. 257/100; 438/26; 257/E33.059; 257/E21.001

(57) ABSTRACT

A light source and method for making the same are disclosed. The light source includes a base member and a lead structure. The lead structure is attached to the base member such that the lead structure extends beyond the base member and has an opening for accessing a surface of the base member. A die containing a light emitting semiconductor device is bonded to the surface of the base member. The die is electrically connected to the lead structure and overlaid with a transparent material. An electrically insulating layer is bonded between the lead structure and the base member, the electrically insulating layer having an opening for accessing the surface of the base member. The electrically insulating layer can be an adhesive for bonding the lead structure to the base member.

### BACKGROUND OF THE INVENTION

Light emitting diodes (LEDs) are an important class of solid-state devices that convert electric energy to light. Improvements in these devices have resulted in their use in light fixtures designed to replace conventional incandescent and fluorescent light sources. The LEDs have significantly longer lifetimes and, in some cases, significantly higher efficiency for converting electric energy to light.

LEDs are particularly attractive as replacements for incandescent bulbs in flashlights and other battery powered devices. LEDs have significantly longer lifetimes than incandescent bulbs and light conversion efficiencies that are several times the efficiency that can be achieved with conventional incandescent bulbs. The increased light conversion efficiency extends the lifetime of the batteries used to power the devices, and hence, battery replacement is reduced. In addition, LED-based lights provide increased ruggedness relative to incandescent lighting, and hence, are better adapted to portable lighting applications.

In addition, LEDs have lifetimes that are greater than the lifetime of incandescent bulbs and fluorescent tubes. This feature is particularly attractive in applications in which the cost of replacing the light bulb is significant. For example, replacing a light bulb in a traffic signal can require a man-hour or more of labor as well as the interruption of the traffic at the intersection.

Unfortunately, the amount of light generated by a single LED is limited. Individual LEDs are limited to a few watts of power, and hence, even though the light output per watt is significantly greater that an incandescent light source, many applications of interest require multiple LEDs to provide sufficient light. For example, flashlights and lighting systems used with infrared cameras typically include an array of individually packaged LEDs. The cost of such systems is substantially increased by the need to accommodate the individually packaged components and the installation of those components.

Heat dissipation is also a significant problem with high power LED light sources. The conversion efficiency of electrical power to light in an LED decreases with increasing junction temperature within the LED. Hence, removing heat from the LEDs is a major factor in the design of any LED light source that generates significant amounts of heat. If the heat is not efficiently removed, the conversion efficiency, and hence, the amount of light that can be generated, is substantially reduced.

Most devices that utilize LEDs are based on some form of pre-packaged LED light source that is configured for attachment to a heat-dissipating surface in the final device. LED packaging solutions typically use either a lead-frame based packaging approach or a printed circuit board based packaging approach, often referred to as chip on a board (COB) packages. In both of these approaches, the heat from the packaged LED-containing die or dies is typically transferred to a heat dissipation surface that is used to transfer the heat to the ambient air, since the packaged LED has insufficient surface area to transfer the heat directly to the ambient environment without operating at a substantially elevated temperature.

In the lead-frame packaging approach the semiconductor chip is mounted to a lead frame based assembly that is encapsulated to provide a packaged part with leads that either exit the encapsulation or are flush with a surface of the package. Electrical interconnection to the final device is made via the external leads that are attached to the final product by a solder or mechanical process. In some lead-frame based packages, the electrical and thermal paths are combined, serving the dual purpose of providing the electrical power to the semiconductor chip and removing the heat generated to either the outside world or to a secondary heat sink. In other lead-frame based packages, the electrical and thermal paths are separated, leaving the lead frame material to serve the sole purpose of providing the electrical power to the semiconductor chip. In this approach a separate thermal path is designed into the package to remove the heat generated.

Typically the lead-frame based approach is facilitated using a molded packaging design where the lead frame material (usually a thin metal layer) is embedded in a packaging material (such as plastic, epoxy, or other moldable materials). In some approaches a secondary heat sink or thermal slug is either inserted into the molded lead frame during the assembly of the package or may be molded into the package during an insert molding process where the lead frame, body, and thermal slug or heat sink are molded together as a separate component to which the semiconductor chip is attached and encapsulated during the assembly process. While this lead frame based packaging approach is used for many semiconductor components today, typically the thermal resistance of such an assembly is high, on the order of 5-20 degrees C/W.

Even in lead frames in which the thermal paths are sufficient to avoid large temperature increases, the surface area of the thermal transfer surfaces are typically too small to allow direct heat dissipation to the ambient air. Hence, some form of secondary substrate is required to transfer heat. This substrate enables the user to connect to the electrical leads and to couple the thermal slug or heat sink of the lead frame based package to an external heat sink or to the overall system assembly, which may act as the heat sink for the lighting system.

Every additional thermal interface in the total integrated solution increases the thermal resistance of the heat-dissipation path, and hence, increases the temperature at which the LEDs must operate. Light output efficiency, output color and product reliability are all dependant on the junction temperature of the semiconductor chip. Hence, reducing the thermal resistance of the heat-dissipation path is an important consideration in light source design. In addition, the need for an additional substrate increases the cost of the lighting system. Hence, other forms of LED packaging have been sought.

In substrate-based packaging, the semiconductor chip containing the LED is mounted on a substrate material such as ceramic, printed circuit board, silicon, or other medium that can be mounted to a secondary substrate for electrical and thermal interconnection within the sub assembly or total lighting system. In the case of a COB type of package, the chip is mounted on a metal core printed circuit board that can be thermally mounted directly to a heat sink of a sub assembly or the total lighting system with a separate electrical interconnection method such as soldered leads or a separate electrical connector.

The first of these approaches has the same drawbacks of the lead frame based packaging approach. Although the substrate based package may reduce the thermal resistance compared to a lead frame based approach, the secondary substrate required to manage the electrical and thermal interconnections still adds a layer of thermal resistance in the lighting solution, increasing the junction temperature of the device resulting in lower efficiency, lower light output, and reduced reliability.

The COB approach introduces problems related to the electrical connection to the electronic driver or power supply. Most products today using the COB approach either use solder pads on the substrate for soldering wires or include a connector mounted to the top surface of the substrate. Solder pads on the substrate, require the user to solder wires from the driver circuit to the assembly, which can be a difficult, expensive task and risks damage to the LED array. In general such an assembly approach is not deemed high volume assembly capable. If connectors are used, the size of the overall solution is typically increased, which results in a more expensive and larger or bulkier solution. Additionally, the cost of the overall system is increased by the cost of the connector on the LED assembly and the mating connector in the final light source.

### SUMMARY OF THE INVENTION

The present invention includes a light source and method for making the same. The light source includes a base member and a lead structure. The lead structure is attached to the base member such that the lead structure extends beyond the base member and has an opening for accessing a surface of the base member. A die containing a light emitting semiconductor device is bonded to the surface of the base member. The die is electrically connected to the lead structure and overlaid with a transparent material. In one aspect of the invention, an electrically insulating layer is bonded between the lead structure and the base member, the electrically insulating layer having an opening for accessing the surface of the base member. The electrically insulating layer can be an adhesive for bonding the lead structure to the base member. In another aspect of the invention, the lead structure includes a rigid connector for coupling power to the die. In a still further aspect of the invention, the base member includes a feature for aligning the base member with an external device.

### BRIEF DESCRIPTION OF THE DRAWINGS

FIG. 1 is a cross-sectional view of a prior art COB packaging scheme.

FIG. 2 is an exploded view of a light source according to one embodiment of the present invention.

FIG. 3 is a cross-sectional view of light source 30 through line 3-3 shown in FIG. 2.

FIG. 4A is a cross-sectional view of light source 30 after the leads in the lead structure have been bent to a configuration that can be utilized for surface mounting.

FIG. 4B is a cross-sectional view of a light source according to this aspect of the present invention.

FIG. 5 is a top view of light source 50.

FIG. 6 is a cross-sectional view of light source 50 when light source 50 is connected to an external connector.

FIGS. 7-10 illustrate the construction of a number of light sources according to the present invention at different stages in the fabrication process.

FIG. 7 is a top view of a number of base light sources at the beginning of the fabrication process.

FIG. 8 is a cross-sectional view through line 8-8 shown in FIG. 7.

FIG. 9 is another cross-sectional view of carrier 61 through a line in which some of the individual leads are visible.

FIG. 10 illustrates an optional ring shaped form 68 that can be placed over lead structure 65 and filled with a transparent encapsulant material 69 to form a protective dome.

### DETAILED DESCRIPTION OF THE PREFERRED EMBODIMENTS OF THE INVENTION

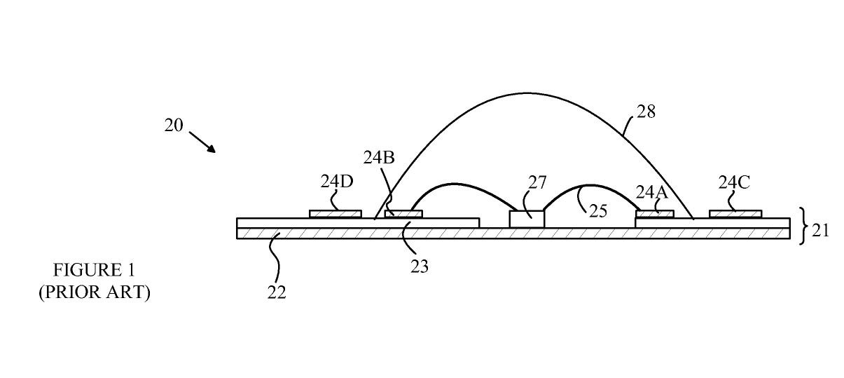

The manner in which the present invention provides its advantages can be more easily understood with reference to FIG. 1, which is a cross-sectional view of a prior art COB packaging scheme. Light source 20 is constructed on a three-layer structure 21 of the type used in printed circuits. Bottom layer 22 is a metal layer on which the dies, such as die 27 are mounted. Layer 22 acts as a heat-conducting layer to remove heat from the dies. A second metallic layer is patterned to provide electrical traces 24A and 24B to which the dies are connected by wire bonds 25. These traces terminate on solder pads 24C and 24D that are used to make electrical connections between light source 20 and the drivers or power source used to power the LEDs on the dies. An insulating layer 23 separates metallic layers 22 and 24. The dies are encapsulated between layer 22 and a protective layer 28 that may include various additives such as phosphors for converting the light from die 27 to light of a different spectrum depending on the precise type of light source.

Light source 20 is limited by the underlying printed circuit board structure used to construct the light source. For example, the thickness of the metal layer that is patterned to provide the traces 24A-24C limits the thickness of the connection structures used to access the dies from the external circuits. In addition, the connection structures overlie the underlying insulation layer 23, and hence, extending the connection structures beyond insulation layer 23 to form a rigid connector or pin is difficult. Hence, connections are made by soldering directly to pads 24C and 24D or by providing a separate connector that is bonded to these pads.

Similarly, the thickness of layer 22 places limitations on the design parameters of light source 20. For example, the thickness of layer 22 limits the heat transfer area that is effectively available for removing heat from die 27 to an area that is immediately under die 27 even when layer 22 is in continuous contact with a larger heat dissipating surface. In addition, it is often useful to provide features on the base structure that provide mechanical connections to the final structure in the finished device that utilizes light source 20. To provide the structures, a separate structure must be connected to layer 22 or the structure must be limited to structures that can be etched into a metal layer of thickness allowed in such printed circuit board structures.

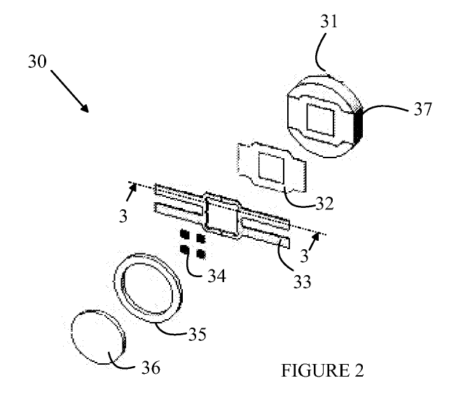

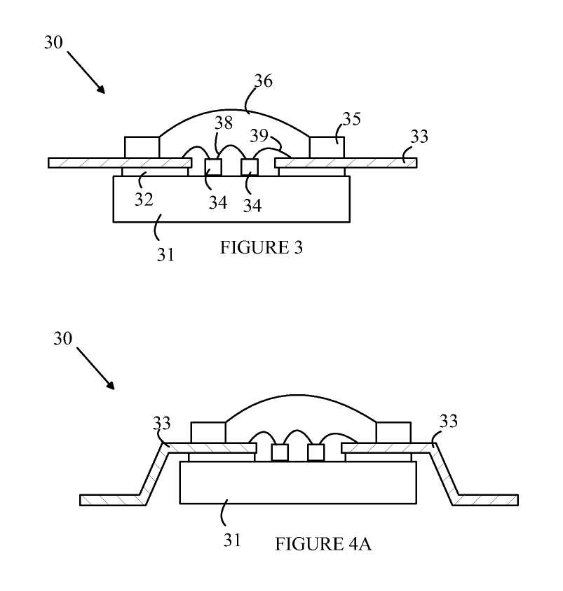

Refer now to FIGS. 2 and 3. FIG. 2 is an exploded view of a light source 30 according to one embodiment of the present invention. FIG. 3 is a cross-sectional view of light source 30 through line 3-3 shown in FIG. 2. Light source 30 is constructed on a base member 31 to which the dies 34 that contain the LEDs are bonded. The dies can be electrically connected to base member 31 or insulated therefrom. The dies can be bonded to base member 31 by a heat-conducting adhesive. Base member 31 provides a low thermal resistance path for transferring heat to the final assembly or to a heat sink. Base member 31 could also include mechanical features for aligning base member 31 with the final assembly. Base member 31 can be constructed from a wide range of materials including metals and alloys.

The dies are connected to the external circuitry by a set of leads that are part of a lead structure 33. The electrical leads provide connection from the dies to the driver or power system in the sub assembly or the lighting system. The electrical leads may be constructed of a flexible material (such as a flexible circuit embedded in polyamide or another similar material) or may be constructed from a more rigid material, similar to those found in a lead frame based packaging approach.

Since the thickness of the leads is not dictated by printed circuit board considerations, the leads can be shaped to provide a connector that extends beyond the boundaries of base member 31. The electrical leads can be configured in many different geometries, and may either be flat or produced (either prior to, during, or after assembly) into a formed lead which may be suitable for a surface mount, through hole, hot bar, glue, laser weld or other electrically conductive assembly methods to connect to the power source or electronic driver in the sub assembly or lighting system.

The electrical leads may be produced as a separate stamped or formed component and then be bonded to the base member during the assembly of the base member or the leads could be bonded during the assembly of the light source. The electrical leads may be bare metal or may be plated with a variety of plating metals including gold, silver, nickel, or others, or a combination of these or other metals. They may also be pre plated with a solder or other materials to aid in assembly into the sub assembly or lighting system. The assembly of the electrical leads to the base member may be made via soldering, gluing, co-firing, or other process either during the assembly of the base member or at a later assembly step in the construction of the LED light source.

An optional insulating layer 32 can be introduced between lead structure 33 and base member 31 to prevent shorts when base member 31 is constructed from an electrical conductor. The insulating layer could be constructed from an adhesive material that acts to bond lead structure 33 to base member 31 in addition to providing electrical insulation.

The dies 34 are bonded to leads in lead structure 33 by wire bonds or other suitable conductors. An exemplary wire bond connecting a die to a lead in lead structure 33 is shown at 39. The wire bonds can also connect the dies to one another as shown at 38. In embodiments in which base member 31 is a conductor and acts as a common electrode for the dies, one of the power connections can be made through base member 31.

In general, the dies and the wire bonds must be protected from the external environment both in terms of physical stresses and moisture. A ring 35 which acts as a mold for a protective layer 36 can be bonded to lead structure 33 and then filled with a transparent medium. Various additives such as phosphors and light scattering particles can be suspended in the transparent medium depending on the particular application. The layer of transparent medium can also be used to bond ring 35, lead structure 33 and base member 31 to one another. The protective layer can be constructed from silicon or epoxy materials that are transparent to the light that is to leave layer 36. This protective layer may also be introduced through over molding.

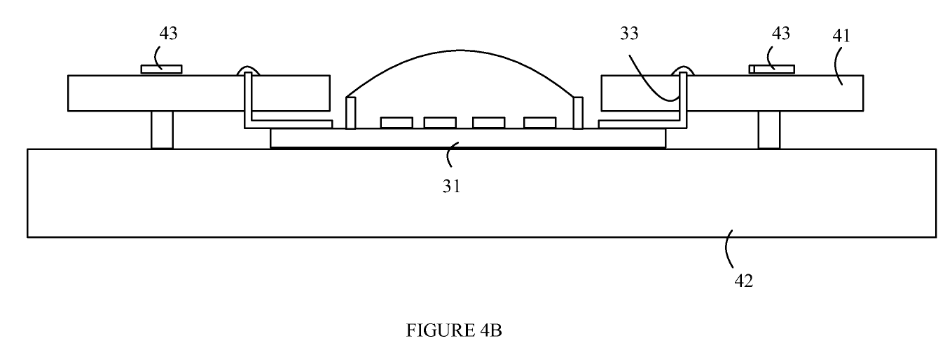

As noted above, lead structure 33 is not constrained by the processes used to construct printed circuit boards, and hence, can have a thickness that enables the leads to be bent to provide various mounting configurations for the light source 30. Refer now to FIG. 4A, which is a cross-sectional view of light source 30 after the leads in lead structure 33 have been bent to a configuration that can be utilized for surface mounting. It should be noted that the leads can be bent after the light source is constructed, or the leads can be bent prior to assembling lead structure 33 into light source 30.

Lead structure 33 can also be configured to provide a connection that bonds the light source to a printed circuit board from the bottom surface of the printed circuit board such that the light source is visible through an opening in the printed circuit board. Refer now to FIG. 4B, which is a cross-sectional view of a light source according to this aspect of the present invention. The light source is constructed on base member 31, which is mounted on the bottom surface of printed circuit board 41. Lead structure 33 is bent to connect to printed circuit board 41 by passing through holes in printed circuit board 41 and then being soldered to the top surface of printed circuit board 41. Base member 31 can be bonded to an additional substrate 42 that provide additional heat dissipation area. The bond can provided by an adhesive bond and/or a mechanical bond such as screws 43 that connect printed circuit board 41 to substrate 42.

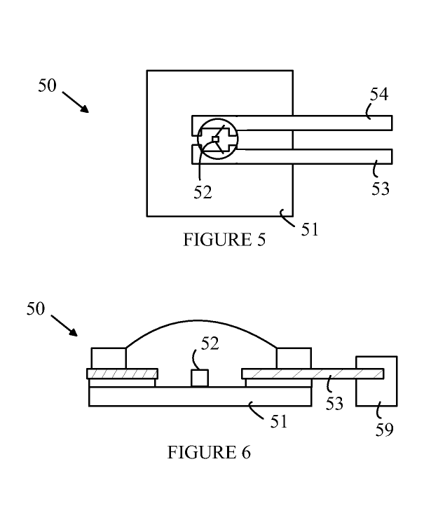

In addition, lead structure 33 can be configured to form a connector that mates with a complimentary connector in the final assembly that utilizes the light source. Refer now to FIGS. 5 and 6, which illustrate another embodiment of a light source according to the present invention. FIG. 5 is a top view of light source 50, and FIG. 6 is a cross-sectional view of light source 50 when light source 50 is connected to an external connector. Light source 50 utilizes a single die 52 that is mounted on a base member 51 and connected to a lead structure having leads 53 and 54 that form a male connector that mates with a female connector 59 on the assembly to which light source 50 is to be connected.

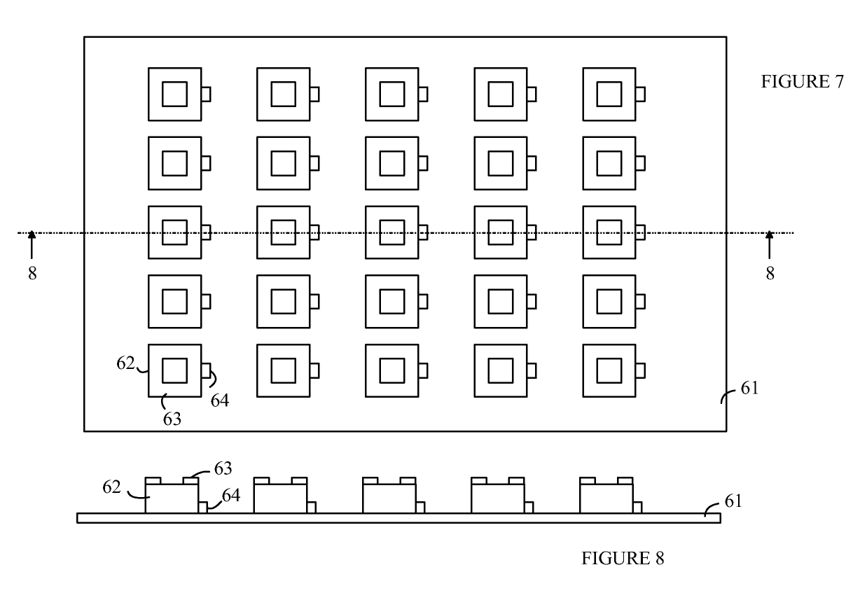

In the above-described embodiments, the light sources were described in terms of the construction of an individual light source. However, light sources according to the present invention can be constructed in groups to further reduce the cost of each light source. Refer now to FIGS. 7-10, which illustrate the construction of a number of light sources according to the present invention at different stages in the fabrication process. Refer first to FIGS. 7 and 8. FIG. 7 is a top view of a number of base light sources at the beginning of the fabrication process, and FIG. 8 is a cross-sectional view through line 8-8 shown in FIG. 7. Initially, the base members 62 are attached to a carrier 61 to form a two-dimensional array. Each base member can include features such as feature 64 for aligning the final light source with a corresponding fixture on an assembly in which the light source is to utilized. The base members can be pre-coated with an electrically insulating adhesive 63 or the insulating layer can be applied after the base members have been attached to carrier 61.

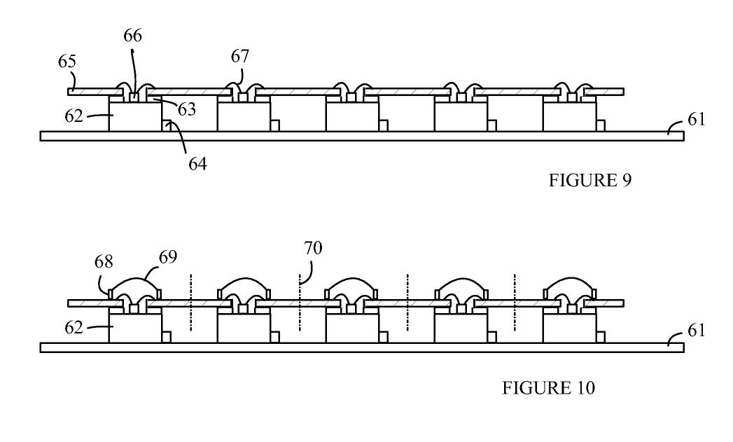

Refer now to FIG. 9, which is another cross-sectional view of carrier 61 through a line in which some of the individual leads are visible. A two-dimensional lead structure 65 is bonded to the insulating adhesive 63. Lead structure 65 can be a lead frame or any other structure that allows all of the leads to be placed over the base members in proper alignment. Insulating adhesive 63 bonds the lead structure to the base members. Lead structure 65 includes openings that are aligned with the openings in the adhesive. The dies 66 that contain the LEDs are inserted through these openings and bonded to the base members. The dies are then connected to the corresponding leads in lead structure 65 by wire bonds such as wire bond 67 shown in FIG. 9.

Referring to FIG. 10, an optional ring shaped form 68 can then be placed over lead structure 65 and filled with a transparent encapsulant material 69 to form a protective dome that protects the dies and wire bonds as well as bonding the various components together. Alternatively, the structure could be over-molded with an optical compound to provide the protective dome. The molding compound could include phosphors or other compounds that alter the spectrum of the light generated by the LEDs. Finally, the individual light sources can be singulated by cutting lead structure 65 at locations between the base members as shown at 70.

The above-described embodiments of the present invention have been provided to illustrate various aspects of the invention. However, it is to be understood that different aspects of the present invention that are shown in different specific embodiments can be combined to provide other embodiments of the present invention. In addition, various modifications to the present invention will become apparent to those skilled in the art from the foregoing description and accompanying drawings. Accordingly, the present invention is to be limited solely by the scope of the following claims.

What is claimed is:

1. A light source comprising:
a base member;
a lead structure attached to said base member, said lead structure extending beyond said base member, said lead structure having an opening for accessing a surface of said base member;
a die containing a light emitting semiconductor device bonded to said surface of said base member;
an electrical connection that connects said die to said lead structure; and
a layer of transparent material overlying said die.

2. The light source of claim 1 further comprising bonding an electrically insulating layer between said lead structure and said base member, said electrically insulating layer having an opening for accessing said surface.

3. The light source of claim 2 wherein said lead structure is bonded to said base member with an electrically insulating adhesive.

4. The light source of claim 1 further comprising a raised ring structure over said opening to contain said transparent medium.

5. The light source of claim 1 further comprising a transparent dome over said opening.

6. The light source of claim 1 wherein said at least one lead is connected to said LED by a wire bond.

7. The light source of claim 1 wherein said base member comprises a feature for aligning said base member with an external device.

8. The light source of claim 1 wherein said lead structure comprises a rigid connector for coupling power to said die.

9. A method for fabricating a light source comprising:
providing a base member;
bonding a lead structure to said base member, said lead structure extending beyond said base member, said lead structure having an opening for accessing a surface of said base member;
bonding a die containing a light emitting semiconductor device to said surface of said base member;
connecting at least one lead on said die to a lead in said lead structure; and
covering said die with a transparent medium.

10. The method of claim 9 further comprising bonding an electrically insulating layer between said lead structure and said base member, said electrically insulating layer having an opening for accessing said surface.

11. The method of claim 10 wherein said lead structure is bonded to said base member with an electrically insulating adhesive.

12. The method of claim 9 further comprising bonding a raised ring structure over said opening to contain said transparent medium.

13. The method of claim 9 further comprising molding a dome over said opening.

14. The method of claim 9 wherein said at least one lead is connected to said LED by a wire bond.

15. The method of claim 9 wherein said base member comprises a feature for aligning said base member with an external device.

16. The method of claim 9 wherein said lead structure comprises a rigid connector for coupling power to said die.

17. A method for fabricating a light source comprising:
providing a plurality of base members arranged in a two-dimensional array on a carrier;
bonding a lead structure to each of said base members, said lead structure having an opening for accessing a surface of each of said base members;
bonding a die containing a light emitting semiconductor device to said surface of each of said base members;
connecting at least one lead on each of said dies to a corresponding lead in said lead structure;
covering said dies with a transparent medium; and
dividing said lead structure to provide a plurality of individual light sources.

18. The method of claim 17 further comprising bonding an electrically insulating layer between said lead structure and said base member, said electrically insulating layer having an opening for accessing said surface.

19. The method of claim 18 wherein said lead structure is bonded to said base member with an electrically insulating adhesive.

20. The method of claim 17 further comprising bonding a raised ring structure over said opening to contain said transparent medium.

21. The method of claim 17 further comprising molding a dome over said opening.

22. The method of claim 17 wherein said at least one lead is connected to said LED by a wire bond.

23. The method of claim 17 wherein said base member comprises a feature for aligning said base member with an external device.

24. The method of claim 17 wherein said lead structure comprises a rigid connector for coupling power to said die.
